(19) United States
(12) Patent Application Publication
(10) Pub. No.: US 2019/0355782 A1
(43) Pub. Date: Nov. 21, 2019

(54) IMAGING ARRAY WITH EXTENDED DYNAMIC RANGE

(71) Applicant: BAE Systems Imaging Solutions Inc., San Jose, CA (US)

(72) Inventors: Hung T. Do, San Jose, CA (US); R. Daniel McGrath, Lexington, MA (US)

(73) Assignee: BAE Systems Imaging Solutions Inc., San Jose, CA (US)

(21) Appl. No.: 16/476,900

(22) PCT Filed: Jan. 25, 2017
(86) PCT No.: PCT/US2017/014976

§ 371 Date: Jul. 10, 2019

(51) Int. Cl. H01L 27/148; H04N 5/378; H04N 5/359; H04N 5/3745; H01L 27/146; H04N 5/355

(52) U.S. Cl. CPC H01L 27/14887; H04N 5/378; H04N 5/3591; H04N 5/355; H01L 27/14643; H01L 27/14612; H01L 27/14806; H04N 5/37452

(57) ABSTRACT

An imaging array and method for using the same are disclosed. The imaging array includes a plurality of pixel sensors connected to a bit line, each pixel sensor includes a photodetector that includes a photodiode, a floating diffusion node, and a buffer connected to the floating diffusion node that produces a pixel output signal having a voltage that is a monotonic function of a voltage on the floating diffusion node. Each pixel sensor also include an overflow capacitor connected to the photodiode by an overflow transfer gate that allows photocharge in excess of a predetermined charge to flow onto the overflow capacitor. The charge accumulated on the photodiode and the overflow capacitor are combined to provide an improved dynamic range for the pixel sensors.

### BACKGROUND

CMOS image sensors that can detect very low light levels are now available. Improvements in noise rejection have resulted in detectors that have noise levels that are a fraction of an electron; thus making individual photon counting possible. While such sensors can provide images in extremely low light, the photodiodes saturate at high light levels. Hence, such sensors have a limited dynamic range.

Pixel sensors with multiple photodiodes have been proposed to extend the dynamic range. In such sensors, one photodiode is sensitive to low light levels and another has a much lower light conversion rate, and hence, can be used to provide a light measurement when the low light photodiode saturates. However, the use of multiple photodiodes presents other challenges, since the photodiodes are not identical, and hence, can have different spectral responses.

### SUMMARY

The present invention includes an apparatus and method for using the same. The apparatus includes a plurality of pixel sensors connected to a bit line, each pixel sensor includes a photodetector that includes a photodiode, a floating diffusion node, and a buffer connected to the floating diffusion node that produces a pixel output signal having a voltage that is a monotonic function of a voltage on the floating diffusion node. Each pixel sensor also includes a bit line gate that connects the pixel output signal to the bit line in response to a row select signal, a reset gate that connects the floating diffusion node to a first reset voltage source in response to a reset signal, a first transfer gate that connects the photodiode to the floating diffusion node in response to a first transfer signal, an overflow capacitor connected to the floating diffusion node via a second transfer gate that connects the overflow capacitor to the floating diffusion node in response to a second transfer signal, and an overflow transfer gate that connects the photodiode to the overflow capacitor in response to a overflow transfer gate signal.

In one aspect of the invention, the overflow transfer gate signal is adjusted to a level that causes charge to flow to the overflow capacitor rather than the floating diffusion node when a charge generated by the photodiode exceeds an overflow threshold value.

In another aspect of the invention, the buffer includes a source follower having a gate connected to the floating diffusion node.

In another aspect of the invention, the apparatus includes a controller that generates the first and second sampling signals, the reset signal, the first and second transfer signals, and the overflow transfer gate signal. In another aspect of the invention, the controller causes the photodiode and the overflow capacitor in each of the pixel sensors to be reset to a reset voltage.

In another aspect of the invention, the controller isolates the photodiodes from the floating diffusion nodes in each of the pixel sensors such that a photocharge generated by light striking the photodiode is first accumulated on the photodiode until the photodiode reaches a predetermined level of stored photocharge, any excess photocharge beyond this predetermined level is stored on the overflow capacitor.

In another aspect of the invention, the controller determines a first photocharge stored on the overflow capacitor and a second photocharge stored on the photodiode after an exposure period for each of the pixel sensors, the controller combining the first and second photocharge to provide a measure of an amount of light received by each pixel sensor during an exposure.

The present invention also includes a method of operating an imaging array which includes a plurality of pixels sensors in which each pixel sensor includes a photodiode that measures an intensity of light incident on the photodiode in that pixel sensor during an exposure, the photodiodes being characterized by a maximum photocharge that can be stored in each photodiode during an exposure. The method includes providing an overflow path in each of the pixel sensors, the overflow path collecting photocharge in excess of the maximum photocharge, measuring the collected charge that passed through the overflow path during the exposure and measuring the photocharge stored on the photodiode after the exposure, and combining the measured collected charge and the photocharge stored on the photodiode after the exposure to arrive at measurement of a pixel intensity for the exposure corresponding to the pixel sensor.

In another aspect of the invention, measuring the overflow path in each of the pixel sensors includes a capacitor in each of the pixel sensors that has been precharged to a reset voltage prior to the exposure and connected to the photodiode by an overflow gate that passes charge when a voltage on the photodiode is less than a threshold value and wherein measuring the collected charge after the exposure includes measuring a voltage on the capacitor after the exposure.

### BRIEF DESCRIPTION OF THE DRAWINGS

FIG. 1 is a schematic drawing of a CMOS imaging array that utilizes a pixel sensor according to one embodiment of the present invention.

FIG. 2 illustrates a pixel sensor according to one embodiment of the present invention.

FIG. 3A illustrates the various control voltages and signal voltages as a function of time during a readout cycle.

FIG. 3B illustrates the control signal timings in an embodiment which Vₒᵤₜₚ is always greater than or equal to Vₒᵤₜₘ.

### DETAILED DESCRIPTION

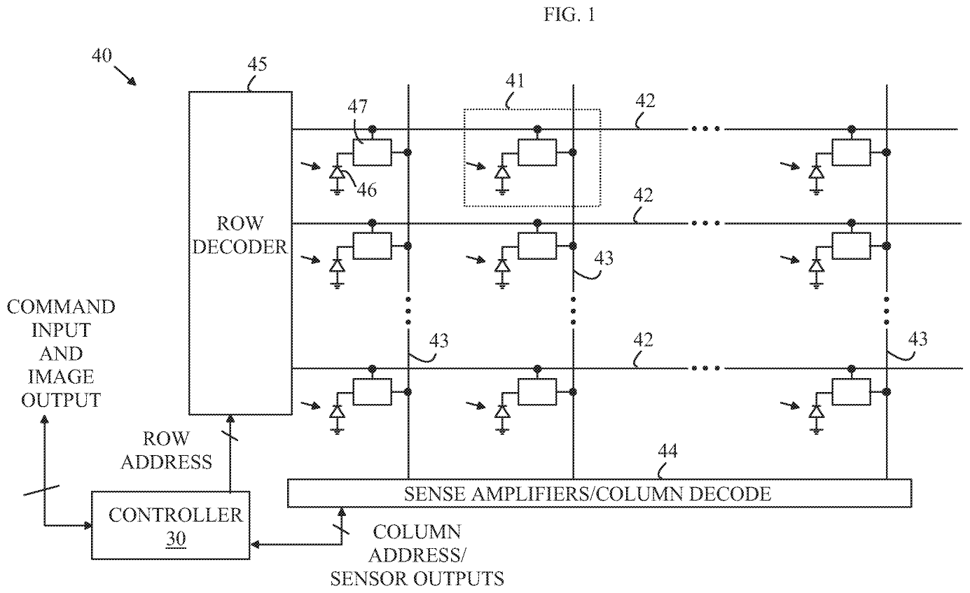

Refer now to FIG. 1, which is a schematic drawing of a CMOS imaging array that utilizes a pixel sensor according to one embodiment of the present invention. Imaging array 40 is constructed from a rectangular array of pixel sensors 41. Each pixel sensor includes a photodiode 46 and an interface circuit 47. The details of the interface circuit depend on the particular pixel design. However, all of the pixel sensors include a gate that is connected to a row line 42 that is used to connect that pixel sensor to a bit line 43. The specific row that is enabled at any time is determined by a row address that is input to a row decoder 45. The row select lines are a parallel array of conductors that run horizontally in the metal layers over the substrate in which the photodiodes and interface circuitry are constructed.

Each of the bit lines terminates in a column processing circuit 44 that typically includes sense amplifiers and column decoders. The bit lines are a parallel array of conductors that run vertically in the metal layers over the substrate in which the photodiode and interface circuitry are constructed. Each sense amplifier reads the signal produced by the pixel that is currently connected to the bit line processed by that sense amplifier. The sense amplifiers may generate a digital output signal by utilizing an analog-to-digital converter (ADC). At any given time, a single pixel sensor is read out from the imaging array. The specific column that is read out is determined by a column address that is utilized by a column decoder to connect the sense amplifier/ADC output from that column to circuitry that is external to the imaging array. The sequencing of the control signals and other functions are performed by a controller 30. To simplify the drawings, the connections between controller 30 and the various control lines have been omitted from the drawing.

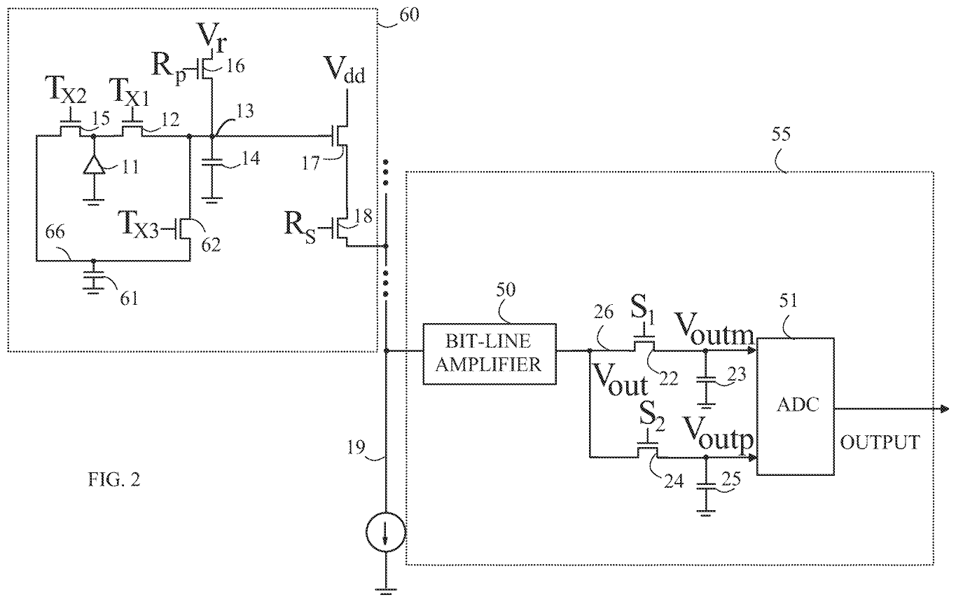

Refer now to FIG. 2, which illustrates a pixel sensor according to one embodiment of the present invention. Pixel 60 includes a photodiode 11 that collects the photocharge during an exposure. A transfer gate 12 allows the accumulated charge to be transferred from photodiode 11 to floating diffusion node 13 in response to signal Tₓ₁. For the purposes of the present discussion, a floating diffusion node is defined to be an electrical node that is not tied to a power rail, or driven by another circuit. Floating diffusion node 13 is characterized by a parasitic capacitor 14 having a capacitance, C_{FD}. The collected charge alters the voltage of floating diffusion node 13 from a reset voltage value that is set prior to the transfer. The amount of reduction in the floating diffusion node voltage provides a measure of the photocharge that was transferred.

A reset gate 16 is used to set the voltage on floating diffusion node 13 prior to the charge being transferred, or to reset photodiode 11 prior to an exposure. The voltage on floating diffusion node 13 is amplified by a source follower transistor 17. When pixel 60 is to be read out, a signal on gate transistor 18 connects the output of source follower transistor 17 to a bit line 19 that is shared by all of the pixel sensors in a given column. For the purposes of the present discussion, a bit line is defined to be a conductor that is shared by a plurality of columns of pixel sensors and carries a voltage signal indicative of the voltage at the floating diffusion node in a pixel sensor that is connected to the hit line through a transfer gate.

Each bit line terminates in a column processing circuit 55. Column processing circuit 55 includes a bit-line amplifier 50 and two sample and hold circuits whose functions will be described in more detail below. The first sample and hold circuit comprises gate 22 and capacitor 23, and the second sample and hold circuit comprises gate 24 and capacitor 25. The outputs of these sample and hold circuits are processed by ADC 51 to provide the output value for the pixel sensor currently connected to bit line 19. The manner in which the sample and hold circuits are used will be discussed in more detail below.

Pixel 60 also includes an overflow capacitor 61 that collects the photocharge generated by photodiode 11 after photodiode 11 saturates. At the beginning of an exposure, photodiode 11 and overflow capacitor 61 are set to a reset voltage determined by Vᵣ. As photocharge accumulates on photodiode 11, the voltage on photodiode 11 decreases until photodiode 11 saturates. At a voltage determined by the gate voltage on gate 15, the excess charge flows through gate 15 and onto the combination of overflow capacitor 61, capacitor 14 (i.e., the parasitic capacitance of floating diffusion node 13), and the parasitic capacitances of gate 62, which remains in a conducting state throughout the exposure. Hence, at the end of the exposure any overflow charge can be determined by measuring the decrease in voltage at floating diffusion node 13 from the reset voltage.

After the overflow charge has been measured, floating diffusion node 13 is again reset and gate 62 placed in a non-conducting state. The reset voltage on floating diffusion node 13 is then measured to provide a reference value. The photocharge that remains on photodiode 11 is then determined by opening gate 12 and measuring the decrease in voltage at floating diffusion node 13 resulting from the transfer of charge to floating diffusion node 13.

The output voltage from hit-line amplifier 50 on node 26 will be denoted by Vₒᵤₜ in the following discussion. This output voltage is stored at various times on sample and hold capacitors 23 and 25. The stored voltages are used by controller 30 shown in FIG. 1 to generate the pixel values that makeup the final image. The stored analog voltages can be digitized by ADCs in the column decode circuitry or by ADCs that are part of controller 30. The various control signals shown in FIG. 2 are generated by controller 30. The connections between controller 30 and the various gates have been omitted from the drawing to simplify the drawing.

The manner in which a pixel exposure is measured will now be discussed in more detail. An exposure can be viewed as consisting of three phases. The first phase is a reset and integration phase in which floating diffusion node 13 and node 66 are reset to a reset voltage determined by Vᵣ. During the reset, gates 12, 16, and 62 are placed in a conducting state. After the reset, gate 12 is set to a non-conducting state, thereby isolating photodiode 11 from floating diffusion node 13. As charge is integrated on photodiode 11 during the exposure, which starts when photodiode 11 is isolated from floating diffusion node 13, the photocharge is first isolated on photodiode 11. However, as photodiode 11 saturates, the voltage on photodiode 11 decreases to the point at which charge will flow through gate 15. The voltage at which charge flows through gate 15 is determined by the potential of signal Tₓ₂ which remains constant throughout the exposure and readout phases.

During the exposure period, gate 62 remains in a conducting state, and hence, the overflow charge is distributed between capacitor 61, capacitor 14, and the parasitic capacitance associated with gate 62, these three capacitors being effectively connected in parallel between floating diffusion node 13 and ground. At the end of the exposure period, the photocharge from the exposure is split between photodiode 11 and these parallel-connected capacitors for pixel sensors in which the photodiode has saturated. In the first phase of the readout, referred to as the overflow charge phase, the voltage on floating diffusion node is measured and compared to the reset voltage at the beginning of the exposure phase.

Once the overflow charge is measured, the second phase of the readout, referred to as the photodiode charge phase, begins. In this phase, gate 62 is placed in a non-conducting state and floating diffusion node is reset. The voltage on floating diffusion node 13 is read and then gate 12 is opened to allow the photocharge stored on photodiode 11 to be transferred to floating diffusion node 13. The voltage on floating diffusion node 13 is then read again to determine the amount of photocharge that was transferred to floating diffusion node 13.

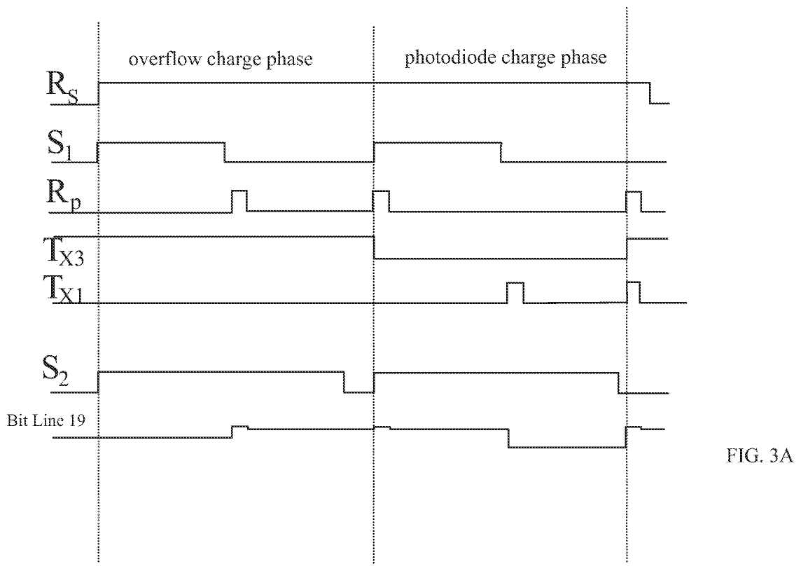

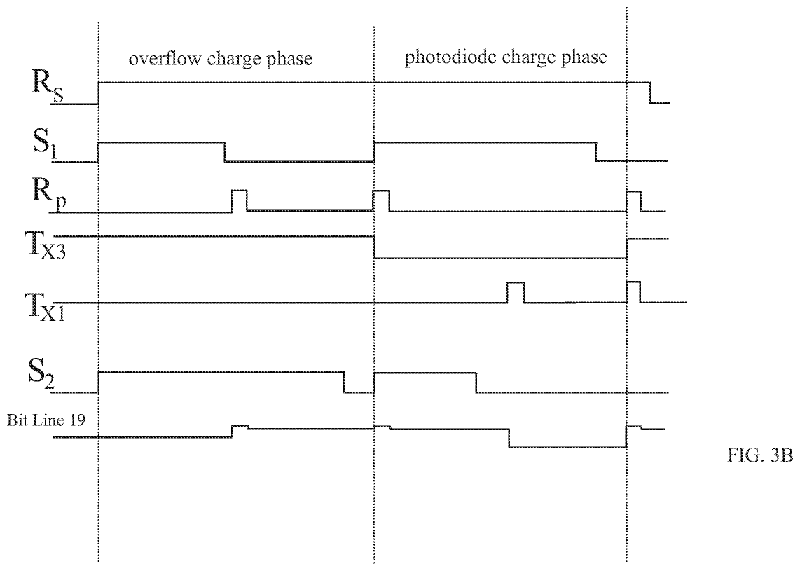

Refer now to FIG. 3A, which illustrates the various control voltages and signal voltages as a function of time during a readout cycle. After the last readout cycle, but before the current readout cycle, floating diffusion node 13, capacitor 61 and photodiode 11 were all reset at the beginning of the exposure that is now to be read out. This reset is accomplished by placing gates 12, 16, and 62 in the conducting state, followed by placing gates 12 and 16 in the non-conducting state. In one exemplary embodiment, the time at which this reset takes place depends on the length of the desired exposure.

The readout phase can be viewed as consisting of two sub-phases, referred to as the overflow charge phase and the photodiode charge phase. During the overflow charge phase, the overflow charge that accumulated during the exposure is measured. After the overflow charge phase, the charge that was stored on the photodiode is measured during the photodiode charge phase. Each charge is measured by computing the difference between the voltage at floating diffusion node 13 after floating diffusion node 13 is reset and the voltage at floating diffusion node 13 after the relevant charge has been transferred to floating diffusion node 13. The readout phase commences when the pixel in question is connected to bit line 19 by setting Rₛ high as shown in FIG. 3A. At this point in time, the potential on floating diffusion node 13 already reflects the overflow charge that has accumulated during the exposure period. In the first part of the overflow charge phase, the voltage on floating diffusion node 13 is captured on sample and hold capacitor 23 by placing gate 22 in the conducting state, as indicated by a first sampling signal, S₁, going high in FIG. 3A. The overflow charge is determined by measuring the difference between this voltage and the reset voltage on floating diffusion node 13, when floating diffusion node 13 is reset. Hence, in the second part of the overflow charge phase, floating diffusion node 13 and capacitor 61 are reset by taking the pixel reset control, Rₚ, high. The reset voltage is then captured on sample and hold capacitor 25 as indicated by a second sampling signal, S₂. The difference between the voltages on sample and hold capacitors 23 and 25 is then digitized by an ADC that is part of controller 30 to provide a measurement of the overflow charge during the exposure.

The photodiode charge phase begins by isolating floating diffusion node 13 and measuring the reset potential on floating diffusion node 13 after the reset. The reset potential is stored on sample and hold capacitor 23. Then, gate 12 is placed in a conducting state and the charge from photodiode 11 is transferred to floating diffusion node 13, which lowers the voltage on floating diffusion node 13. This voltage is then stored on sample and hold capacitor 25. The difference between the voltages on sample and hold capacitors 23 and 25 is then digitized by an ADC that is part of controller 30 to provide a measure of the charge accumulated on photodiode 11 during the exposure. The sum of these charges is used to provide the pixel signal corresponding to the pixel sensor that is connected to the bit line.

It should be noted that the exposure does not stop until the charge stored on the photodiode is transferred to the floating diffusion node. However, the overflow charge is measured prior to this point in time. Hence, any charge that overflows in the period between measuring the overflow charge and the transfer of charge to the floating diffusion node from the photodiode is lost. This lost charge, however, is small, as the time period is typically less than 4 μsec, while the typical exposure in a moving picture is approximately 17 msec.

As noted above, the voltages stored on the sample and hold capacitors must be digitized and subtracted from one another. Typically, there is one ADC for each bit line to reduce the readout time. The number of columns of pixel sensors in an imaging array is in the thousands. Hence, it is advantageous to reduce the complexity of the column readout circuitry. One method for reducing the complexity of the readout circuitry is to combine the subtraction hardware with the ADC function. One simple form of ADC that can be used is a count up ADC which includes a register that drives a digital-to-analog converter (DAC). The counter counts clock pulses until the output of the DAC exceeds the input voltage. Normally, the initial value in the register is zero.

In one aspect of the invention, the counter counts clock pulses starting from an initial counter value of zero only after the DAC output exceeds a first analog input, and the counting stops after the DAC output exceeds a second analog input. This embodiment provides both the subtraction function and the digitization function in the same time needed to perform digitization of the second analog input. To utilize such an ADC, the values to be digitized must be routed to the ADC inputs such that the lower voltage is always at a specified input and the higher voltage is at the other input. For example, in the embodiment shown in FIG. 2, Vₒᵤₜₘ should be less than or equal to Vₒᵤₜₚ for ADC 51 to operate in this mode.

The problem in such an implementation arises from the order in which signal and reset voltages are generated in the two phases discussed above. For the purposes of this discussion, the reset voltage will be referred to as the reference voltage, and the depleted reset voltage obtained by transferring charge to the floating diffusion node after the floating diffusion node has been set to the reference voltage will be referred to as the signal voltage. As noted above, the signal voltage for the overflow charge phase is generated before the reference voltage for that charge. However, in the photodiode charge phase, the reference voltage is generated before the signal voltage.

Refer now to FIG. 3B, which illustrates the control signal timings in an embodiment in which Vₒᵤₜₚ is always greater than or equal to Vₒᵤₜₘ. In this exemplary embodiment, the roles of switches S₁ and S₂ are reversed in the photodiode charge phase relative to the overflow charge phase, and hence, the reference voltage is always stored on capacitor 25 while the signal voltage is always stored on capacitor 23.

To provide a significant expansion in the dynamic range of the pixel sensor, the sum of the capacitances of capacitor 61 and the parasitic capacitance of gate 62 must be significantly greater than the capacitance of floating diffusion node 13. The price for providing such large capacitances is an increase in the noise at the exposure range in which the exposure is close to the maximum storage of the well in photodiode 11. Denote the sum of capacitances of capacitor 61 and the parasitic capacitance of gate 62 by C′. In one exemplary embodiment, C_{FD}=4 fF, C′=28 fF, and the floating diffusion node has a full voltage swing of 1.2 V. The readout noise in this exemplary embodiment in the photodiode charge phase is 0.7 e−. It can be shown that the noise at an exposure at which the photodiode just saturates is increased by about 16 percent. However, the dynamic range of the pixel sensor is increased by 18 dB. Increasing the capacitance of capacitor 61 further increases the dynamic range.

The above-described embodiments utilize a source follower in each pixel to buffer the floating diffusion node from the bit line while generating a signal that varies with the voltage on the floating diffusion node. Embodiments in which the source follower is replaced by an amplifier or other circuit that generates a pixel output signal that is a monotonic function of the voltage on the floating diffusion node could also be utilized provided the increase in the size of the pixel is acceptable. For the purposes of the present discussion, the term buffer will be defined to include such an amplifier or other circuit as well as a source follower.

The above-described embodiments of the present invention have been provided to illustrate various aspects of the invention. However, it is to be understood that different aspects of the present invention that are shown in different specific embodiments can be combined to provide other embodiments of the present invention. In addition, various modifications to the present invention will become apparent from the foregoing description and accompanying drawings. Accordingly, the present invention is to be limited solely by the scope of the following claims.

What is claimed is:

1. An apparatus comprising a plurality of pixel sensors connected to a bit line, each pixel sensor comprising a photodetector comprising:
a photodiode;
a floating diffusion node;
a buffer connected to said floating diffusion node that produces a pixel output signal having a voltage that is a monotonic function of a voltage on said floating diffusion node;
a bit line gate that connects said pixel output signal to said bit line in response to a row select signal;
a reset gate that connects said floating diffusion node to a first reset voltage source in response to a reset signal;
a first transfer gate that connects said photodiode to said floating diffusion node in response to a first transfer signal;
an overflow capacitor connected to said floating diffusion node via a second transfer gate that connects said overflow capacitor to said floating diffusion node in response to a second transfer signal; and
an overflow transfer gate that connects said photodiode to said overflow capacitor in response to a overflow transfer gate signal.

2. The apparatus of claim 1 wherein said overflow transfer gate signal is adjusted to a level that causes charge to flow to said overflow capacitor rather than said floating diffusion node when a charge generated by said photodiode exceeds an overflow threshold value.

3. The apparatus of claim 1 wherein said buffer comprises a source follower having a gate connected to said floating diffusion node.

4. The apparatus of claim 1 further comprising a controller that generates said first and second sampling signals, said reset signal, said first and second transfer signals, and said overflow transfer gate signal.

5. The apparatus of claim 4 wherein said controller causes said photodiode and said overflow capacitor in each of said pixel sensors to be reset to a reset voltage.

6. The apparatus of claim 5, wherein said controller isolates said photodiode from said floating diffusion node in each of said pixel sensors such that a photocharge generated by light striking said photodiode is first accumulated on said photodiode until said photodiode reaches a predetermined level of stored photocharge, any excess photocharge beyond this predetermined level being stored on said overflow capacitor.

7. The apparatus of claim 6 wherein said controller determines a first photocharge stored on said overflow capacitor and a second photocharge stored on said photodiode after an exposure period for each of said pixel sensors, said controller combining said first and second photocharges to provide a measure of an amount of light received by each pixel sensor during said exposure.

8. A method of operating an imaging array comprising a plurality of pixel sensors, each pixel sensor comprising a photodiode that measures an intensity of light incident on said photodiode in that pixel sensor during an exposure, said photodiodes being characterized by a maximum photocharge that can be stored in each photodiode during an exposure, said method comprising:
providing an overflow path in each of said pixel sensors, said overflow path collecting photocharge in excess of said maximum photocharge;
measuring said collected charge that passed through said overflow path during said exposure and measuring said photocharge stored on said photodiode after said exposure; and
combining said measured collected charge and said photocharge stored on said photodiode after said exposure to arrive at a measurement of a pixel intensity for said exposure corresponding to said pixel sensor.

9. The method of claim 8 wherein measuring said overflow path in each of said pixel sensors comprises a capacitor in each of said pixel sensors that has been precharged to a reset voltage prior to said exposure and connected to said photodiode by an overflow gate that passes charge when a voltage on said photodiode is less than a threshold value and wherein measuring said collected charge after said exposure comprises measuring a voltage on said capacitor after said exposure.
